(19) United States
(12) Patent Application Publication
(10) Pub. No.: US 2012/0241926 A1
(43) Pub. Date: Sep. 27, 2012

(54) INTEGRATED CIRCUIT PACKAGING SYSTEM WITH LEVELING STANDOFF AND METHOD OF MANUFACTURE THEREOF

(76) Inventors: Zigmund Ramirez Camacho, Singapore (SG); Henry Descalzo Bathan, Singapore (SG); Emmanuel Espiritu, Singapore (SG)

(21) Appl. No.: 13/070,362

(22) Filed: Mar. 23, 2011

(51) Int. Cl. H01L 23/495; H01L 21/60; H01L 21/56

(52) U.S. Cl. 257/666; 438/124; 438/118; 257/E21.504; 257/E21.506; 257/E23.04

(57) ABSTRACT

A method of manufacture of an integrated circuit packaging system includes: providing a lead; mounting an integrated circuit adjacent the lead; molding an encapsulation encapsulating the lead and the integrated circuit; and forming a leveling standoff protruded from the same surface of the encapsulation as the lead with the integrated circuit between the lead and the leveling standoff electrically isolated from the lead and the integrated circuit.

### TECHNICAL FIELD

The present invention relates generally to an integrated circuit packaging system, and more particularly to an integrated circuit packaging system having leveling standoff.

### BACKGROUND ART

Electronic system manufacturers continue to demand integrated circuits with higher performance and reliability along with a reduced physical size and manufacturing cost. As the electronic systems grow in complexity to meet today's rapidly changing business and consumer needs, the semiconductors also grow in size.

As the semiconductors grow in size, there is a higher chance of extreme warpage resulting from thermal expansion and shrinkage mismatch between the lead frame and the semiconductor. Some solutions involve removing the integrated circuit attach pad from the lead frame.

As the semiconductors grow in complexity, the semiconductors can have asymmetrically arranged connections, such as leads and pads. For example, some quad flat no-leads (QFN) packages and thin small-outline packages (TSOP) have the contact pads on the bottom surface and only on one side of the package.

Semiconductors used in high power circuits often require thicker lead frame metal to support high current levels and adequately dissipate heat generated by the circuit. The increased thickness in lead frame metal, removal of the integrated circuit attach pad, along with asymmetrical arrangement of the terminal pads can cause uneven support for the package and affect the mountability of the package.

Thus, a need still remains for an integrated circuit packaging system providing low cost manufacturing, improved yields, reduction of integrated circuit package dimensions, and flexible stacking and integration configurations. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a lead; mounting an integrated circuit adjacent the lead; molding an encapsulation encapsulating the lead and the integrated circuit; and forming a leveling standoff protruded from the same surface of the encapsulation as the lead with the integrated circuit between the lead and the leveling standoff electrically isolated from the lead and the integrated circuit.

The present invention provides an integrated circuit packaging system including: a lead; an integrated circuit mounted adjacent the lead; an encapsulation encapsulating the lead and the integrated circuit; and a leveling standoff protruded from the same surface of the encapsulation as the lead with the integrated circuit between the lead and the leveling standoff electrically isolated from the lead and the integrated circuit.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system along a line 1-1 of FIG. 2 in a first embodiment of the present invention.

FIG. 2 is a bottom view of the integrated circuit packaging system in the first embodiment of the present invention.

FIG. 3 is a top view of a lead frame.

FIG. 4 is a cross-sectional view of the lead frame along line 4-4 of FIG. 3.

FIG. 5 is the structure of FIG. 4 having the components attached thereon and encapsulated.

FIG. 6 is the integrated circuit packaging system having the leveling standoff.

FIG. 7 is a cross-sectional view of an integrated circuit packaging system along a line 7-7 of FIG. 8 in a second embodiment of the present invention.

FIG. 8 is a bottom view of the integrated circuit packaging system in the second embodiment of the present invention.

FIG. 9 is a top view of a lead frame having holes.

FIG. 10 is a cross-sectional view of the lead frame along line 10-10 of FIG. 9.

FIG. 11 is the structure of FIG. 10 having the components attached thereon and encapsulated.

FIG. 12 is the structure of FIG. 11 with the lead frame exposed.

FIG. 13 is the integrated circuit packaging system having the leveling standoffs.

FIG. 14 is a flow chart of a method for manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the FIGs. is arbitrary for the most part. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact between elements. The term “processing” as used herein includes deposition of material, patterning, exposure, development, etching, cleaning, molding, and/or removal of the material or as required in forming a described structure.

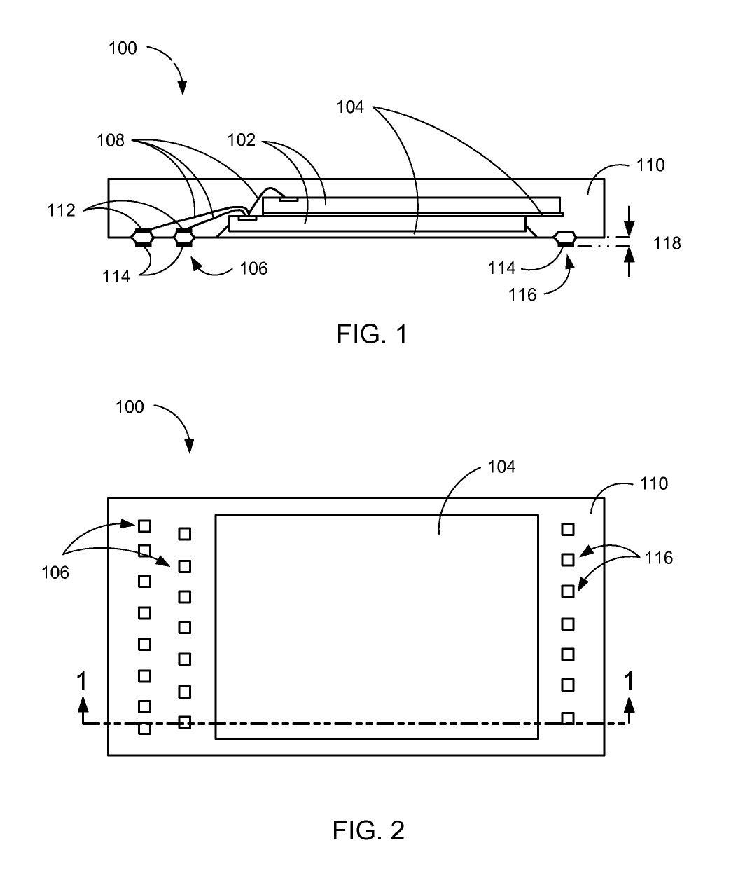

Referring now to FIG. 1, therein is shown a cross-sectional view of an integrated circuit packaging system 100 along a line 1-1 of FIG. 2 in a first embodiment of the present invention. The integrated circuit packaging system 100 can have integrated circuits 102, adhesive layers 104, leads 106, bond wires 108, and an encapsulation 110.

The integrated circuits 102 are semiconductor devices that have active circuitry fabricated thereon. For example, the integrated circuits 102 can be flip chips or wire-bond integrated circuits. The integrated circuits 102 can be made from silicon wafers, silicon germanium wafers, gallium arsenide wafers, and other wafers that are capable having active circuitry fabricated thereon.

The adhesive layers 104 are layers of substance that provides or promotes adhesion between the integrated circuits 102, substrates, interposers, or a combination thereof. For example, the adhesive layers 104 can be epoxy adhesives or double-sided tapes.

The leads 106 are structures made of conductive materials, such as copper or gold, or a set of layers having conductive property that can be used to relay electrical signals. For example, the leads 106 can function as input/output (IO) pads for the integrated circuits 102 or relay signals between components, such as integrated circuits and resistors.

The leads 106 can have bonding contacts 112 and system contacts 114. The bonding contacts 112 are metal attached to the top surface of the leads 106. For example, the bonding contacts 112 can be nickel, tin, gold, palladium, or metal alloy.

The system contacts 114 are metal attached to the bottom surface of the leads 106 and other components of the integrated circuit packaging system 100. The system contacts 114 can be similar to the bonding contacts 112. For example, the system contacts 114 can be nickel, tin, gold, palladium, or metal alloy. Also, for example, the system contacts 114 and the bonding contacts 112 can be part of pre-plated lead frames (PPF).

The bond wires 108 are conductive wires that relay electrical signals to and from the integrated circuits 102. The bond wires 108 can be insulated wires or bare metal wires, such as gold or copper.

The encapsulation 110 is a structure that encapsulates or surrounds electrical components to prevent physical damage or corrosion in an integrated circuit packaging system 100. The encapsulation 110 can also hold the encapsulated components in place relative to each other. The encapsulation 110 can be made of materials such as ceramic, plastic, or epoxy.

The encapsulation 110 can expose the bottom of one of the adhesive layers 104. For example, the bottom surface of the encapsulation 110 can be planar with the bottom surface of the instance of the adhesive layers 104 that is on the bottom. Also, for example, the encapsulation 110 can expose a portion of one or more of the adhesive layers 104 on the bottom surface of the encapsulation 110. The encapsulation 110 can otherwise encapsulate the rest of the adhesive layers 104.

The integrated circuit packaging system 100 can have leveling standoffs 116. The leveling standoffs 116 are electrically isolated structures that provide vertical offset to integrated circuit packaging system 100. The leveling standoffs 116 can be physically and electrically isolated from the integrated circuits 102 and the leads 106.

The leveling standoffs 116 can protrude from the bottom surface of the encapsulation 110. For example, the leveling standoffs 116 can protrude away from the bottom surface of the encapsulation 110 and extend downward.

The leveling standoffs 116 can be made of conductive materials or insulators. For example, the leveling standoffs 116 can be made of gold, copper, tin, nickel, metal alloy, or a combination thereof. Also, for example, the leveling standoffs 116 can be made of ceramic, plastic, or epoxy. The leveling standoffs 116 can have the system contacts 114 attached to the bottom surface.

A portion of the leveling standoffs 116 can be embedded within and encapsulated by the encapsulation 110. For example, the leveling standoffs 116 can be on the bottom surface of the integrated circuit packaging system 100. The top portion of the leveling standoffs 116 can be contacting the encapsulation 110 and encapsulated by the encapsulation 110.

The leveling standoffs 116 can have an offset height 118. The offset height 118 is the vertical length of the leveling standoffs 116 exposed by the encapsulation 110. For example, the offset height 118 can be the length of the portion of the leveling standoffs 116 extending downward from the bottom surface of the encapsulation 110.

The offset height 118 of the leveling standoffs 116 can be same as the vertical length of the leads 106 exposed by the encapsulation 110. For example, the offset height 118 can be equal to the length of the portion of the leads 106 extending downward from the bottom surface of the encapsulation 110.

Continuing with the example, the offset height 118 can be the distance between the bottom surface of the encapsulation 110 and the surface or plane having the integrated circuit packaging system 100 resting or attached thereon. The leveling standoffs 116 can be attached to the next level system (not shown) with solder.

The leads 106 and the leveling standoffs 116 can be arranged opposite to each other on the same surface. For example, the leads 106 can be on the bottom surface of the encapsulation 110 and located closer to one side than the other. The leveling standoffs 116 can be on the bottom surface and located near the opposite side as the leads 106. The integrated circuit packaging system 100 can have the integrated circuits 102 between the leads 106 and the leveling standoffs 116.

The leveling standoffs 116 can have a tapered shape. The system contacts 114 can be narrower than the portion planar with the surface of the encapsulation 110. The tapered shape can be a characteristic of forming the leveling standoffs 116 from etching away a frame having the leveling standoffs 116. The process of forming the leveling standoffs 116 will be discussed in detail below.

It has been discovered that the integrated circuit packaging system 100 provides improved stability during the assembly process. The leveling standoffs 116 electrically and physically isolated from the integrated circuits 102 and the leads 106 give rise to the reliability by increasing the number of mounting points for the integrated circuit packaging system 100 without changing or rearranging the physical layout of the electrical connections.

It has further been discovered that the integrated circuit packaging system 100 provides improved structural stability and integrity. The leveling standoffs 116 having the offset height 118 equal to the length of the portion of the leads 106 extending away from the encapsulation 110 give rise to the benefit.

Providing a consistent distance above the mounting surface equal to the offset height 118 provides even distribution of forces across the integrated circuit packaging system 100 to support itself. The even distribution of forces and increase in weight bearing points provided by the leveling standoffs 116 eliminate overloading portions of the integrated circuit packaging system 100 and improve its structural stability and integrity.

As a specific example, the leveling standoffs 116 can prevent potential delamination of the integrated circuit pad due to high stress points in thin small-outline packages (TSOP) or quad flat no-leads (QFN) packages having leads only near one edge. Also, as a specific example, the leveling standoffs 116 can prevent structural damage due to high stress points in QFN packages with the integrated circuit pad removed for warpage prevention purposes.

As a further specific example, the leveling standoffs 116 can provide board level reliability and improved structural integrity for QFN packages having the bond pads on one side of the package, such as in memory devices and “stair-stacked” devices. The leveling standoffs 116 can be used to further attach and secure the QFN packages to provide board level reliability. The leveling standoffs 116 can provide the increased loading points and even distribution of the loading force for QFN packages as discussed above.

It has further yet been discovered that the integrated circuit packaging system 100 provides improved warpage control while maintaining reliability. The leveling standoffs 116 protruding from the same surface as the leads 106 with the integrated circuits 102 between the leads 106 and the leveling standoffs 116 give rise to the benefit. The leveling standoffs 116 arranged opposite the leads 106 eliminate the need for an integrated circuit attach pad for structural support and attach points. Eliminating the integrated circuit attach pad allows for improvement in the warpage control, while the leveling standoffs 116 maintain the structural support and attach points, and thus the reliability, of the integrated circuit packaging system 100.

It has also been discovered that the integrated circuit packaging system 100 provides improved reliability. The leveling standoffs 116 allow the leads 106 to be planar with the next system level and avoid tipping towards the side of the integrated circuit packaging system 100 if the leveling standoffs 116 were not present and resulting in the leads 106 breaking their connections to the next system level.

For illustrative purposes, the leveling standoffs 116 are shown in arranged in a column and parallel to the arrangement of the leads 106. However, it is understood that the leveling standoffs 116 can be arranged differently. For example, the leveling standoffs 116 can be arranged in non-linear patterns or have just one occurrence the leveling standoffs 116 on the side opposing the leads 106.

Referring now to FIG. 2, therein is shown a bottom view of the integrated circuit packaging system 100 in the first embodiment of the present invention. The bottom view shows the encapsulation 110, the leads 106, the leveling standoffs 116, and one of the adhesive layers 104.

The exposure of one of the adhesive layers 104 can be characteristic of etching away the frame that was used to hold the integrated circuits 102 of FIG. 1 in place during manufacturing process. The process of manufacturing the integrated circuit packaging system 100 will be discussed in detail below. A line 1-1 for the cross-section view of FIG. 1 is also shown.

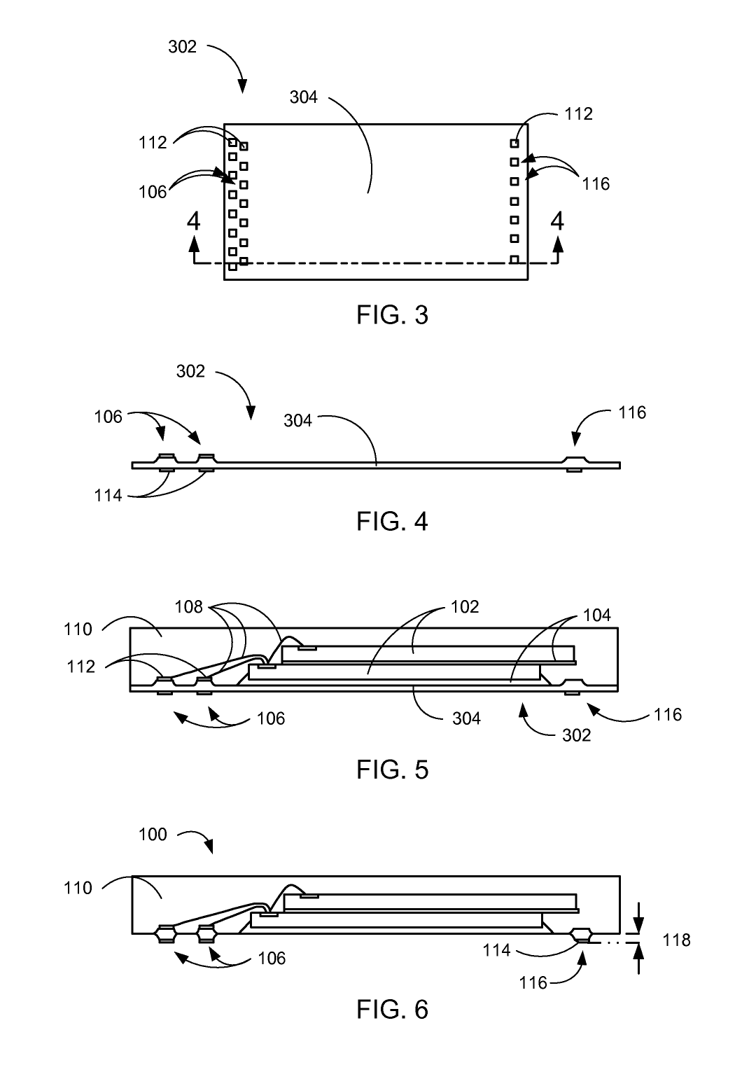

Referring now to FIG. 3, therein is shown a top view of a lead frame 302. A line 4-4 for the cross-section view of FIG. 4 is also shown.

The lead frame 302 is an arrangement of conductive material that provides mechanical support to integrated circuit integrated circuits during assembly process and in finished products. For example, the lead frame 302 can be made of copper, aluminum, metal alloy, or a combination thereof.

The lead frame 302 can have the leads 106 and an integrated circuit pad 304. The integrated circuit pad 304 is a portion of the lead frame 302 used for holding the integrated circuits 102 of FIG. 1 in place during manufacturing process, in the finished product, or a combination thereof.

The lead frame 302 can have the bonding contacts 112 attached over the leads 106. In other examples, the lead frame 302 can have the bonding contacts 112 attached over the leveling standoffs 116. For example, the bonding contacts 112 can be attached through known plating methods or using adhesives. Also for example, the lead frame 302 having the bonding contacts 112 can be a pre-plated lead frame (PPF).

Referring now to FIG. 4, therein is shown a cross-sectional view of the lead frame along line 4-4 of FIG. 3. The lead frame 302 can be half-etched to form the top portions of the leads 106 and the leveling standoffs 116. The lead frame 302 can be half-etched by removing a top portion of the lead frame 302 through an etching process, such as chemical or laser etching. The tapered shaped, with the top portion of the leads 106 and the leveling standoffs 116 wider than that of the bottom portion, can be characteristic of the etching process.

The lead frame 302 can have the system contacts 114 attached under the leads 106 and the leveling standoffs 116. For example, the system contacts 114 can be attached by being plated or using an adhesive. Also, for example, the lead frame 302 having the system contacts 114 can be a pre-plated lead frame (PPF).

The lead frame 302 can have the same thickness at the portions for the leads 106 and the leveling standoffs 116. The integrated circuit pad 304 can also have a uniform thickness therein. The leads 106 can the leveling standoffs 116 can have the system contacts planar to each other. The leads 106 can be on one side of the integrated circuit pad 304 and the leveling standoffs 116 can be on the opposite side of the integrated circuit pad.

Referring now to FIG. 5, therein is shown the structure of FIG. 4 having the components attached thereon and encapsulated. A first instance of the adhesive layers 104 can be applied over the integrated circuit pad 304. A first instance of the integrated circuits 102 can be placed on the first instance of the adhesive layers 104 and thereby attached to the integrated circuit pad 304.

A second instance of the adhesive layers 104 can be applied over the first instance of the integrated circuits 102. A second instance of the integrated circuits 102 can be placed on the second instance of the adhesive layers 104 and thereby attached to the first instance of the integrated circuits 102. The integrated circuits 102 can be stair-stacked with the integrated circuits 102 horizontally offset to each other. The integrated circuit on top can create an overhang over a portion of the lead frame 302, the leveling standoffs 116, or a combination thereof with the stair-stacked structure.

The bond wires 108 can be attached to the integrated circuits 102 and the leads 106. One end of the bond wires 108 can be attached to the integrated circuits 102. The other end of the integrated circuits 102 can be attached to the integrated circuits 102 or the bonding contacts 112 of the leads 106.

The encapsulation 110 can be molded on top of the lead frame 302. The material for the encapsulation 110 can be flowed and extruded through a mold and over the lead frame 302, the integrated circuits 102, and the bond wires 108. The material for the encapsulation 110 can contact and surround the top portions of the leveling standoffs 116 along with the other components.

The material for the encapsulation 110 can be set or hardened to complete the molding and form the encapsulation 110. For example, the material for the encapsulation 110 can be set over time or with exposure to light using the properties of the material. The encapsulation 110 can encapsulate the top portions of the leveling standoffs 116 along with the other components.

Referring now to FIG. 6, therein is shown the integrated circuit packaging system 100 having the leveling standoffs 116. Formation of the leveling standoffs 116 can be completed by removing the portions of the lead frame 302 of FIG. 5 not having the system contacts 114, including the integrated circuit pad 304 of FIG. 5.

The lead frame 302 can be etched away with etching process, such as chemical or laser etching. The etching process can leave a tapered shape to the leads 106 and the leveling standoffs 116. The width of the leads 106 can the leveling standoffs 116 can increase from the system contacts 114 to the bottom surface of the encapsulation 110.

The portions of the lead frame 302 having the system contacts 114 can be the leads 106 and the leveling standoffs 116. The leveling standoffs 116 can be electrically isolated from the integrated circuits 102 and the leads 106 after etching away the lead frame 302.

The thickness of the integrated circuit pad 304 can be the offset height 118 after etching away the lead frame 302. The leads 106 and the leveling standoffs 116 can extend away from the bottom surface of the encapsulation 110 by the offset height 118 since the lead frame 302 had the same thickness at the portions for the leads 106 and the leveling standoffs 116. Also, since the lead frame 302 had a planar overall shape, the bottom surface of the integrated circuit packaging system 100 can be generally planar and have a clearance equal to the leveling standoffs 116 when attached or placed above a planar surface (not shown).

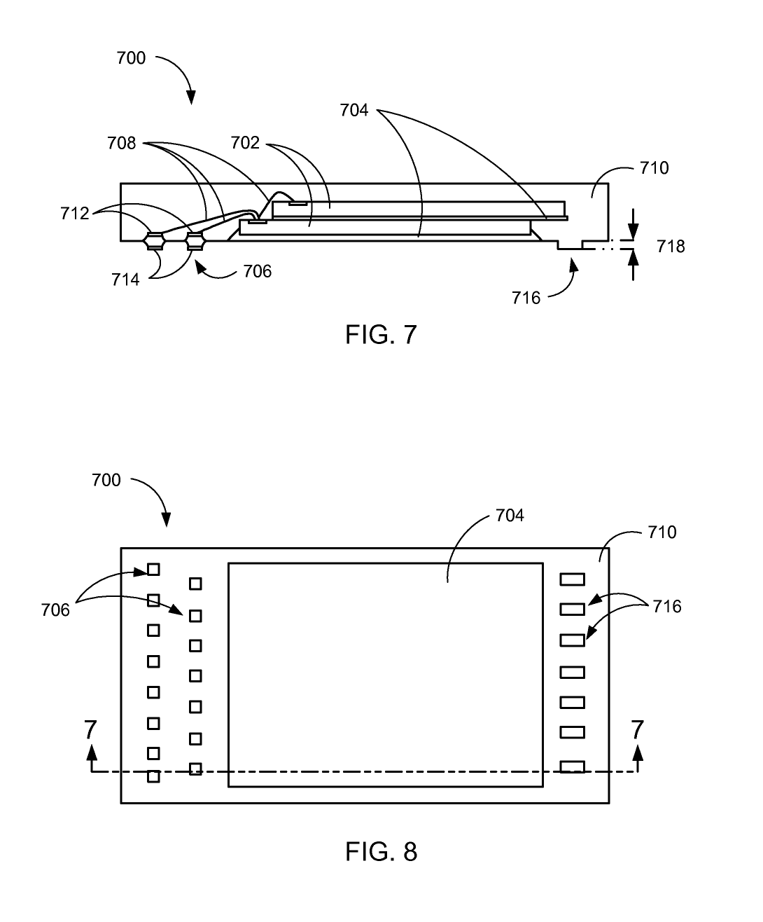

Referring now to FIG. 7, therein is shown a cross-sectional view of an integrated circuit packaging system 700 along a line 7-7 of FIG. 8 in a second embodiment of the present invention. The integrated circuit packaging system 700 can be similar to the integrated circuit packaging system 100 of FIG. 1. The integrated circuit packaging system 700 can have integrated circuits 702, adhesive layers 704, leads 706, bond wires 708, and an encapsulation 710.

The integrated circuits 702 are semiconductor devices that have active circuitry fabricated thereon. For example, the integrated circuits 702 can be flip chips or wire-bond integrated circuits. The integrated circuits 702 can be made from silicon wafers, silicon germanium wafers, gallium arsenide wafers, and other wafers that are capable having active circuitry fabricated thereon.

The adhesive layers 704 are layers of substance that provides or promotes adhesion between the integrated circuits 702, substrates, interposers, or a combination thereof. For example, the adhesive layers 704 can be epoxy adhesives or double-sided tapes.

The leads 706 are structures made of conductive materials, such as copper or gold, or a set of layers having conductive property that can be used to relay electrical signals. For example, the leads 706 can function as input/output (JO) pads for the integrated circuits 702 or relay signals between components, such as integrated circuits and resistors.

The leads 706 can have bonding contacts 712 and system contacts 714. The bonding contacts 712 are metal attached to the top surface of the leads 706. For example, the bonding contacts 712 can be nickel, tin, gold, palladium, or metal alloy.

The system contacts 714 are metal attached to the bottom surface of the leads 706 and other components of the integrated circuit packaging system 700. The system contacts 714 can be similar to the bonding contacts 712. For example, the system contacts 714 can be nickel, tin, gold, palladium, or metal alloy. Also, for example, the system contacts 714 and the bonding contacts 712 can be part of pre-plated lead frames (PPF).

The bond wires 708 are conductive wires that relay electrical signals to and from the integrated circuits 702. The bond wires 708 can be insulated wires or bare metal wires, such as gold or copper.

The encapsulation 710 is a structure that encapsulates or surrounds electrical components to prevent physical damage or corrosion in an integrated circuit package. The encapsulation 710 can also hold the encapsulated components in place relative to each other. The encapsulation 710 can be made of materials such as ceramic, plastic, or epoxy.

The encapsulation 710 can expose the bottom of one of the adhesive layers 704. For example, the bottom surface of the encapsulation 710 can be planar with the bottom surface of the instance of the adhesive layers 704 that is on the bottom. Also, for example, the encapsulation 710 can expose a portion of one or more of the adhesive layers 704 on the bottom surface of the encapsulation 710. The encapsulation 710 can otherwise encapsulate the rest of the adhesive layers 704.

The integrated circuit packaging system 700 can have leveling standoffs 716. The leveling standoffs 716 are electrically isolated structures that provide vertical offset to integrated circuit packages.

The leveling standoffs 716 can protrude away from the bottom surface of the encapsulation 710. For example, the leveling standoffs 716 can protrude away from the bottom surface of the encapsulation 710 and extend downward.

The leveling standoffs 716 can be made of conductive materials or insulators. For example, the leveling standoffs 716 can be made of gold, copper, tin, nickel, metal alloy, or a combination thereof. Also, for example, the leveling standoffs 716 can be made of ceramic, plastic, or epoxy. The leveling standoffs 716 can have the system contacts 714 attached to the bottom surface.

A portion of the leveling standoffs 716 can be embedded within and encapsulated by the encapsulation 710. For example, the leveling standoffs 716 can be on the bottom surface of the integrated circuit packaging system 700. The top portion of the leveling standoffs 716 can be contacting the encapsulation 710 and encapsulated by the encapsulation 710.

The leveling standoffs 716 can have an offset height 718. The offset height 718 is the vertical length of the leveling standoffs 716 exposed by the encapsulation 710. For example, the offset height 718 can be the length of the portion of the leveling standoffs 716 extending downward from the bottom surface of the encapsulation 710.

The offset height 718 of the leveling standoffs 716 can be same as the vertical length of the leads 706 exposed by the encapsulation 710. For example, the offset height 718 can be equal to the length of the portion of the leads 706 extending downward from the bottom surface of the encapsulation 710.

Continuing with the example, the offset height 718 can be the distance between the bottom surface of the encapsulation 710 and the surface or plane having the integrated circuit packaging system 700 resting or attached thereon. The leveling standoffs 716 can be attached to the next level system (not shown) with adhesives, such as epoxy, glue, or double sided tape.

The leads 706 and the leveling standoffs 716 can be arranged opposite to each other on the same surface. For example, the leads 706 can be on the bottom surface of the encapsulation 710 and located closer to one side than the other. The leveling standoffs 716 can be on the bottom surface and located near the opposite side as the leads 706. The integrated circuit packaging system 700 can have the integrated circuits 702 between the leads 706 and the leveling standoffs 716.

The leveling standoffs 716 can have a tapered shape. The system contacts 714 can be narrower than the portion planar with the surface of the encapsulation 710. The tapered shape can be a characteristic of forming the leveling standoffs 716 from etching away a frame having the leveling standoffs 716. The process of forming the leveling standoffs 716 will be discussed in detail below.

It has been discovered that the integrated circuit packaging system 700 provides improved stability during the assembly process. The leveling standoffs 716 electrically and physically isolated from the integrated circuits 702 and the leads 706 give rise to the reliability by increasing the number of mounting points for the integrated circuit packaging system 700 without changing or rearranging the physical layout of the electrical connections.

It has further been discovered that the integrated circuit packaging system 700 provides improved structural stability and integrity. The leveling standoffs 716 having the offset height 718 equal to the length of the portion of the leads 706 extending away from the encapsulation 710 give rise to the benefit.

Providing a consistent distance above the mounting surface equal to the offset height 718 provides even distribution of forces across the integrated circuit packaging system 700 to support itself. The even distribution of forces and increase in weight bearing points provided by the leveling standoffs 716 eliminate overloading portions of the integrated circuit packaging system 700 and improve its structural stability and integrity.

As a specific example, the leveling standoffs 716 can prevent potential delamination of the integrated circuit pad due to high stress points in TSOP and QFN packages having contacts on one side. Also, as a specific example, the leveling standoffs 716 can prevent structural damage due to high stress points in QFN packages with the integrated circuit pad removed for warpage prevention purposes.

As a further specific example, the leveling standoffs 716 can provide board level reliability and improved structural integrity for QFN packages having the bond pads on one side of the package, such as in memory devices and “stair-stacked” devices. The leveling standoffs 716 can be used to further attach and secure the QFN packages to provide board level reliability. The leveling standoffs 716 can provide the increased loading points and even distribution of the loading force for QFN packages as discussed above.

It has further yet been discovered that the integrated circuit packaging system 700 provides improved warpage control while maintaining reliability. The leveling standoffs 716 protruding from the same surface as the leads 706 with the integrated circuits 702 between the leads 706 and the leveling standoffs 716 give rise to the benefit. The leveling standoffs 716 arranged opposite the leads 706 eliminate the need for an integrated circuit attach pad for structural support and attach points. Eliminating the integrated circuit attach pad allows for improvement in the warpage control, while the leveling standoffs 716 maintain the structural support and attach points, and thus the reliability, of the integrated circuit packaging system 700.

It has also been discovered that the integrated circuit packaging system 700 provides improved reliability. The leveling standoffs 716 allow the leads 706 to be planar with the next system level and avoid tipping towards the side of the integrated circuit packaging system 700 if the leveling standoffs 716 were not present and resulting in the leads 706 breaking their connections to the next system level.

For illustrative purposes, the leveling standoffs 716 are shown in arranged in a column and parallel to the arrangement of the leads 706. However, it is understood that the leveling standoffs 716 can be arranged differently. For example, the leveling standoffs 716 can be arranged in non-linear patterns or have just one occurrence the leveling standoffs 716 on the side opposing the leads 706.

Referring now to FIG. 8, therein is shown a bottom view of the integrated circuit packaging system 700 in the second embodiment of the present invention. The bottom view shows the encapsulation 710, the leads 706, the leveling standoffs 716, and one of the adhesive layers 704.

The exposure of one of the adhesive layers 704 can be characteristic of etching away the frame that was used to hold the integrated circuits 702 in place during manufacturing process. The process of manufacturing the integrated circuit packaging system 700 will be discussed in detail below. A line 7-7 for the cross-section view of FIG. 7 is also shown.

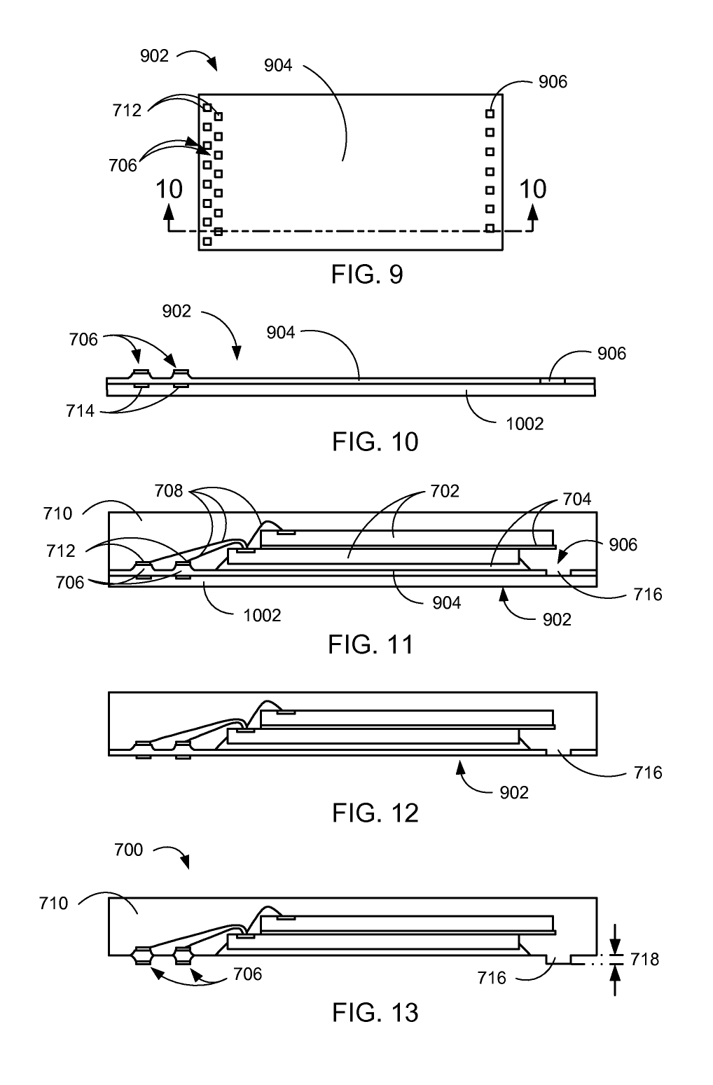

Referring now to FIG. 9, therein is shown a top view of a lead frame 902 having holes 906. A line 10-10 for the cross-section view of FIG. 10 is also shown.

The lead frame 902 is an arrangement of conductive material that provides mechanical support to integrated circuit integrated circuits during assembly process and in finished products. For example, the lead frame 902 can be made of copper, aluminum, metal alloy, or a combination thereof.

The lead frame 902 can have the leads 706 and an integrated circuit pad 904. The integrated circuit pad 904 is a portion of the lead frame 902 used for holding the integrated circuits 702 of FIG. 7 in place during manufacturing process, in the finished product, or a combination thereof.

The lead frame 902 can have bonding contacts 712 attached over the leads 706. For example, the bonding contacts 712 can be plated through known plating methods or attached with an adhesive. Also, for example, the lead frame 902 having the bonding contacts 712 can be a pre-plated lead frame (PPF).

The lead frame 902 can have the holes 906 for forming the leveling standoffs 716. The holes 906 can be located opposite to the leads 706. For example, from the top view, the leads 706 can be to the left of the integrated circuit pad 904 and the holes 906 can be to the right of the integrated circuit pad 904.

For illustrative purposes, the holes 906 are shown arranged in a column. However, it is understood that the holes 906 can be arranged differently. For example, the holes 906 can have a semi-circular arrangement or scattered as not to form a row or a column. Also, for example, only one instance of the holes 906 may be located on the side opposite to the leads 706.

Referring now to FIG. 10, therein is shown a cross-sectional view of the lead frame 702 along line 10-10 of FIG. 9. The lead frame 902 can be half-etched to form the top portions of the leads 706. The lead frame 902 can be half-etched by removing a top portion of the lead frame 902 through an etching process, such as chemical or laser etching. The tapered shaped, with the top portion of the leads 706 wider than that of the bottom portion, can be characteristic of the etching process.

The lead frame 902 can have the system contacts 714 attached under the leads 706 and the leveling standoffs 716. For example, the system contacts 714 can be plated through known plating methods or attached with an adhesive. Also, for example, the lead frame 902 having the system contacts 714 can be a pre-plated lead frame (PPF).

The integrated circuit pad 904 can have a uniform thickness therein. The lead frame 902 can have the same thickness around the holes 906 as the integrated circuit pad 904. The holes 906 can go through the thickness of the lead frame 902. The leads 706 can be on one side of the integrated circuit pad 904 and the holes 906 for the leveling standoffs 716 of FIG. 9 can be on the opposite side of the integrated circuit pad.

The lead frame 902 can have a coverlay tape 1002. The coverlay tape 1002 is a static resistant tape used during manufacturing process to hold components. For example, coverlay tape 1002 can be used to hold in place or to move the silicon wafers or the substrate. The coverlay tape 1002 can be made of various materials. For example, the coverlay tape 1002 can be polyimide film with silicone adhesives or time setting epoxy adhesives.

The coverlay tape 1002 can be attached to the bottom surface of the lead frame 902. The coverlay tape 1002 can cover the holes 906 at the bottom.

Referring now to FIG. 11 therein is shown the structure of FIG. 10 having the components attached thereon and encapsulated. A first instance of the adhesive layers 704 can be applied over the integrated circuit pad 904. A first instance of the integrated circuits 702 can be placed on the first instance of the adhesive layers 704 and thereby attached to the integrated circuit pad 904.

A second instance of the adhesive layers 704 can be applied over the first instance of the integrated circuits 702. A second instance of the integrated circuits 702 can be placed on the second instance of the adhesive layers 704 and thereby attached to the first instance of the integrated circuits 702. The integrated circuits 702 can be stair-stacked with the integrated circuits 702 horizontally offset to each other. The integrated circuit on top can create an overhang over a portion of the lead frame 902, the leveling standoffs 716, or a combination thereof with the stair-stacked structure.

The bond wires 708 can be attached to the integrated circuits 702 and the leads 706. One end of the bond wires 708 can be attached to the integrated circuits 702. The other end of the integrated circuits 702 can be attached to the integrated circuits 702 or the bonding contacts 712 of the leads 706.

The encapsulation 710 can be molded on top of the lead frame 902. The material for the encapsulation 710 can be flowed and extruded through a mold and over the lead frame 902, the integrated circuits 702, and the bond wires 708. The material for the encapsulation 710 can extruded through the holes 906. The coverlay tape 1002 can stop the material for the encapsulation 710 from flowing beyond the bottom surface of the lead frame 902.

The material for the encapsulation 710 can be set or hardened to complete the molding and form the encapsulation 710. For example, the material for the encapsulation 710 can be set over time or with exposure to light using the properties of the material. The encapsulation 710 can set within the holes 906 to form the leveling standoffs 716.

Referring now to FIG. 12 therein is shown the structure of FIG. 11 with the lead frame 902 exposed. The coverlay tape 1002 of FIG. 11 can be removed to expose the bottom surface of the lead frame 902. The bottom surface of the leveling standoffs 716 can also be exposed.

Referring now to FIG. 13 therein is shown the integrated circuit packaging system 700 having the leveling standoffs 716. Formation of the leveling standoffs 716 can be completed by removing the portions of the lead frame 902 of FIG. 9 not having the system contacts 714 of FIG. 10, including the integrated circuit pad 904 of FIG. 9.

The lead frame 902 can be etched away with etching process, such as chemical or laser etching. The etching process can leave a tapered shape to the leads 706 and the leveling standoffs 716. The width of the leads 706 can the leveling standoffs 716 can increase from the system contacts 714 to the bottom surface of the encapsulation 710. The portions of the lead frame 902 having the system contacts 714 can be the leads 706.

The portions of the encapsulation 710 that were in the holes of FIG. 12 can form the leveling standoffs 716. The leveling standoffs 716 can be electrically isolated from the integrated circuits 702 and the leads 706.

The thickness of the integrated circuit pad 904 can be the offset height 718 after etching away the lead frame 902. The leads 706 and the leveling standoffs 716 can extend away from the bottom surface of the encapsulation 710 by the offset height 718 since the lead frame 902 had a planar overall shape and the coverlay tape 1002 of FIG. 10 was placed to control the offset height 718.

The leads 706 can extend away from the encapsulation 710 more than the offset height 718 due to the thickness of the system contacts 714. However, the thickness of the system contacts 714 is very thin and can be ignored in comparison to the offset height 718. The bottom surface of the integrated circuit packaging system 700 can be generally planar and have a clearance equal to the leveling standoffs 716 when attached or placed above a planar surface (not shown).

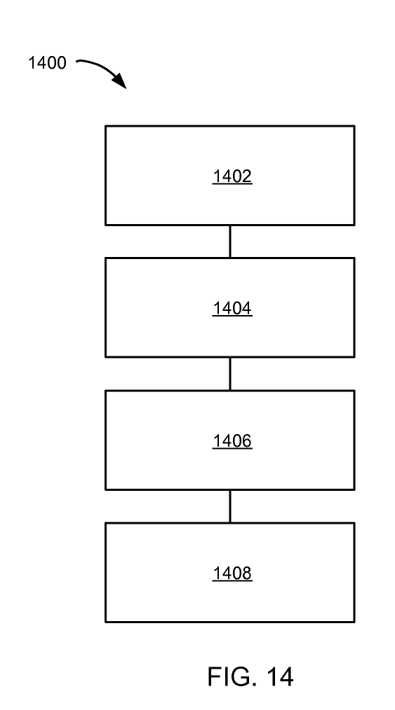

Referring now to FIG. 14, therein is shown a flow chart of a method 1400 for manufacture of the integrated circuit packaging system 100 in a further embodiment of the present invention. The method 1400 includes providing a lead in a block 1402; mounting an integrated circuit adjacent the lead in a block 1404; molding an encapsulation encapsulating the lead and the integrated circuit in a block 1406; and forming a leveling standoff protruded from the same surface of the encapsulation as the lead with the integrated circuit between the lead and the leveling standoff electrically isolated from the lead and the integrated circuit in a block 1408.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the integrated circuit packaging system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit packaging system.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a lead;
mounting an integrated circuit adjacent the lead;
molding an encapsulation encapsulating the lead and the integrated circuit; and
forming a leveling standoff protruded from the same surface of the encapsulation as the lead with the integrated circuit between the lead and the leveling standoff electrically isolated from the lead and the integrated circuit.

2. The method as claimed in claim 1 wherein forming the leveling standoff includes forming the leveling standoff from a portion of the encapsulation.

3. The method as claimed in claim 1 wherein forming the leveling standoff includes forming the leveling standoff from the lead.

4. The method as claimed in claim 1 wherein mounting the integrated circuit includes connecting a bond wire to the lead and the integrated circuit.

5. The method as claimed in claim 1 wherein forming the leveling standoff includes matching an offset height to the vertical difference between the bottom of the lead and the bottom of the encapsulation.

6. A method of manufacture of an integrated circuit packaging system comprising:
providing a lead frame having a lead and an integrated circuit pad;
mounting an integrated circuit on the lead frame;
plating a system contact on the bottom of the lead frame;
attaching an integrated circuit to the integrated circuit pad with an adhesive;
connecting a bond wire to the lead and the integrated circuit;
molding an encapsulation encapsulating the lead frame, the adhesive, and the integrated circuit and exposing a bottom surface of the lead frame; and
forming a leveling standoff with a portion of the lead frame or the encapsulation, with the leveling standoff having a standoff-height protruded away from the bottom of the encapsulation and matching the vertical difference between the bottom of the lead, with the integrated circuit between the lead and the leveling standoff electrically isolated from the lead and the integrated circuit.

7. The method as claimed in claim 6 further comprising attaching a coverlay tape to the bottom of the lead frame.

8. The method as claimed in claim 6 wherein providing the lead includes partially etching a top surface of the lead frame.

9. The method as claimed in claim 6 further comprising etching away the lead frame.

10. The method as claimed in claim 6 wherein
providing the lead frame includes providing the lead frame having a hole;
molding the encapsulation includes extruding the encapsulation over the lead frame and through the hole in the lead frame; and
forming the leveling standoff includes setting the portion of the encapsulation extruded through the hole of the lead frame.

11. An integrated circuit packaging system comprising:
a lead;
an integrated circuit mounted adjacent the lead;
an encapsulation encapsulating the lead and the integrated circuit; and
a leveling standoff protruded from the same surface of the encapsulation as the lead with the integrated circuit between the lead and the leveling standoff electrically isolated from the lead and the integrated circuit.

12. The system as claimed in claim 11 wherein the leveling standoff is a portion of the encapsulation.

13. The system as claimed in claim 11 wherein the leveling standoff is the lead electrically isolated from the integrated circuit.

14. The system as claimed in claim 11 further comprising a bond wire connected to the integrated circuit and the lead.

15. The system as claimed in claim 11 wherein the leveling standoff has an offset height matching the vertical difference between the bottom of the lead and the bottom of the encapsulation.

16. The system as claimed in claim 11 further comprising:
a lead frame having the lead and an integrated circuit pad, and having a system contact on the bottom;
an adhesive attaching the integrated circuit to the integrated circuit pad;
a bond wire connecting the lead and the integrated circuit; and
wherein:
the encapsulation encapsulates the lead frame, the adhesive, and the integrated circuit and exposes a bottom surface of the lead frame;
the leveling standoff is formed from a portion of the lead frame or the encapsulation, with the leveling standoff having a standoff-height protruded away from the bottom of the encapsulation and matching the vertical difference between the bottom of the lead, with the integrated circuit between the lead and the leveling standoff electrically isolated from the lead and the integrated circuit.

17. The system as claimed in claim 16 wherein the leveling standoff having the standoff height matching the vertical difference between the bottom of the lead and the bottom of the encapsulation is characteristic of attaching a coverlay tape to the bottom of the lead frame.

18. The system as claimed in claim 16 wherein the lead frame is partially etched on a top surface.

19. The system as claimed in claim 16 wherein the lead, the leveling standoff, or a combination thereof have a tapered shape exposed by the encapsulation, characteristic of etching away the lead frame.

20. The system as claimed in claim 16 wherein:
the lead frame has a hole; and
the leveling standoff is a portion of the encapsulation set in the hole.
